(19) United States
(12) Patent Application Publication
(10) Pub. No.: US 2024/0030146 A1
(43) Pub. Date: Jan. 25, 2024

(54) MULTICHIP INTERCONNECTING PACKAGING STRUCTURE AND MANUFACTURING METHOD THEREOF

(71) Applicant: Nantong ACCESS Semiconductor CO.,LTD., Jiangsu Province (CN)

(72) Inventors: Xianming CHEN, Jiangsu Province (CN); Yejie HONG, Jiangsu Province (CN); Gao HUANG, Jiangsu Province (CN); Benxia HUANG, Jiangsu Province (CN); Jindong FENG, Jiangsu Province (CN); Guilin ZHU, Jiangsu Province (CN); Yue BAO, Jiangsu Province (CN)

(21) Appl. No.: 18/220,891

(22) Filed: Jul. 12, 2023

(30) Foreign Application Priority Data
Jul. 20, 2022 (CN) 2022108627523

(51) Int. Cl. H01L 23/538; H01L 21/48

(52) U.S. Cl. CPC H01L 23/5385; H01L 21/486; H01L 23/49827

(57) ABSTRACT

A multichip interconnecting packaging structure includes a glass frame, a first line layer and a second line layer respectively provided on the first surface and the second surface of the glass frame, a first via post penetrating through the glass frame, a cavity penetrating through the glass frame, a chip connecting device embedded in the cavity, a first insulating layer filling the cavity to cover the chip connecting device, and a first chip and a second chip provided on the surface of the first line layer, wherein a terminal of the chip connecting device is connected to the first line layer, the first line layer and the second line layer are in conductive communication through the first via post, the first chip and the second chip are connected to the chip connecting device through the first line layer to interconnect the first chip with the second chip.

### CROSS-REFERENCE TO RELATED APPLICATION AND CLAIM OF PRIORITY

This application claims the benefit under 35 USC § 119 of Chinese Patent Application No. 2022108627523, filed on Jul. 20, 2022, in the China Intellectual Property Office, the entire disclosure of which is incorporated herein by reference for all purposes.

### BACKGROUND

### 1. Technical Field

The present application relates to the technical field of electronic device packaging, and in particular to a multichip interconnecting packaging structure and a manufacturing method thereof.

### 2. Background Art

With the increasing development of electronic technology, the performance requirements of electronic products are becoming higher and higher, making electronic devices and circuit board substrate circuits increasingly complex. At the same time, the size requirements of electronic products are becoming smaller and smaller, thinner and thinner, making high-density integration, miniaturization, and multi-functionality of electronic elements such as chips, package substrates, and packaging structures an inevitable trend. As the line width and line spacing of chips become smaller and smaller, it is more and more difficult to continue to miniaturize chips. In order to meet higher electronic product performance, it is generally required to implement a multichip integrated package. In order to implement multichip integrated package miniaturization, it is a trend to implement the interconnection between multiple chips.

The multichip interconnecting packaging structures in the prior art typically utilize a TSV (Through Silicon Via) interposer to achieve chip-to-chip interconnection and chip-to-package-carrier-board interconnection. However, the TSV interposer needs to be manufactured separately, which is expensive. The thickness of a TSV interposer is thick such that the volume of a packaging module is increased, and the short, small, lightweight, and thin packaging module can't be truly realized. The multichip interconnection realized by the TSV interposer has low design freedom. In a 2.5D packaging structure, the chip is mounted to the surface of the TSV interposer, and the interposer and the packaging carrier board are welded to achieve the interconnection, resulting in a relatively low integration.

### SUMMARY

In view of this, the purpose of the present application is to propose a multichip interconnecting packaging structure and a manufacturing method thereof to overcome the defects in the prior art mentioned above.

Based on the above purpose, an embodiment of the present application provides a multichip interconnecting packaging structure, including: a glass frame, a first line layer and a second line layer respectively provided on the first surface and a second surface of the glass frame, a first via post penetrating through the glass frame, a cavity penetrating through the glass frame, a chip connecting device embedded in the cavity, a first insulating layer filling the cavity to cover the chip connecting device, and a first chip and a second chip provided on a surface of the first line layer;
wherein a terminal of the chip connecting device is connected to the first line layer; the first line layer and the second line layer are in conductive communication through the first via post; the first chip and the second chip are connected to the chip connector through the first line layer to interconnect the first chip with the second chip. The manufacturing method for a multichip interconnecting packaging structure

provided in an embodiment of the present application includes the steps below:
(a) preparing a glass frame, forming, on the glass frame, a first via penetrating through the glass frame and a cavity penetrating through the glass frame;
(b) mounting a chip connecting device in a cavity of the glass frame;
(c) forming a first insulating layer in the cavity so as to package the chip connecting device;
(d) forming a first line layer and a second line layer respectively on the first surface and a second surface of the glass frame, and forming a first via post in the first via so that the first line layer and the second line layer are in conductive communication with each other through the first via post; and
(e) mounting a first chip and a second chip to the first line layer, wherein the first chip and the second chip are respectively connected to the chip connector through the first line layer to interconnect the first chip with the second chip.

It can be seen from the above that the present application provides a multichip interconnecting packaging structure and a manufacturing method thereof. According to the present application, a glass frame having a via post is used as an embedded packaging frame, a chip connecting device is embedded and packaged inside the glass frame so as to embed and package the chip connecting device inside the packaging carrier board, thereby forming a packaging carrier board having the chip connecting device, and a terminal of the chip connecting device is led out to an outer layer line pad (namely, the first line layer). Multiple chips (such as the first chip and the second chip) packaged on the glass carrier board can achieve the soldering with the outer layer line pad led out from the chip connecting device, can achieve the interconnection between multiple chips packaged on the multichip interconnecting packaging carrier board and the interconnection between the chips and the substrate, and can achieve high-density integration of a packaging module.

### BRIEF DESCRIPTION OF THE DRAWINGS

In order to illustrate the technical solutions of the present application or in the related art more clearly, the following will briefly introduce the drawings that need to be used in the description of the embodiments or of the related art. Obviously, the drawings in the following description are merely embodiments of the present application. For those of ordinary skills in the art, other drawings can be obtained according to these drawings without involving inventive efforts. FIG. 1 shows a 2.5D packaging structure for implementing multichip

interconnection by using TSV interposer 1 the in related art.

FIG. 2 shows a schematic diagram of a multichip interconnecting packaging structure provided in an embodiment of the present application.

FIGS. 3A to 3K show schematic cross-sectional diagrams of intermediate structures in each step of a manufacturing method for the multichip interconnecting packaging structure in FIG. 2.

### DETAILED DESCRIPTION OF THE EMBODIMENTS

In order to make the purpose, technical solution, and advantages of the present application clearer, the present application will be further described in detail below in conjunction with specific embodiments and with reference to the accompanying drawings.

It needs to be noted that, unless otherwise defined, technical or scientific terms used in the embodiments of the present application shall have the general meaning as understood by one of ordinary skills in the art to which the present application belongs.

The “first”, “second”, and similar words used in the embodiments of the present application do not denote any order, quantity, or importance, but are only used to distinguish different constituent parts. Similar words such as “including” or “containing” mean that the element or object appearing before the word covers the element or object listed appearing after the word and its equivalents, without excluding other elements or objects. Similar terms such as “connection” or “connected” are not limited to physical or mechanical connections, but can include electrical connections, whether direct or indirect. “Up”, “down”, “left”, “right”, etc. are only used to represent the relative position relationship. When the absolute position of the described object changes, the relative position relationship may also change accordingly.

FIG. 1 shows a 2.5D packaging structure for implementing multichip interconnection by using TSV interposer 1 the in related art.

Some 2.5D packaging structures using TSV interposer 1 to realize multichip interconnection, as shown in FIG. 1, need to arrange the TSV interposer 1 between a packaging carrier board 2 and the chip 3 so as to realize chip-to-chip interconnection and chip-to-packaging-carrier-board-2 interconnection by using the TSV interposer 1. However, this kind of structure needs to make the TSV interposer 1 separately, which makes the cost high. The thickness of TSV interposer 1 is thick, which increases the volume of a packaging module such that the short, small, lightweight, and thin packaging module can't be truly realized. The TSV interposer 1 achieving multichip interconnection will lead to low design freedom. The 2.5D packaging structure chip is mounted to the surface of the TSV interposer 1, and the interconnection is achieved through the welding of the TSV interposer 1 and the packaging carrier board 2, resulting in a relatively low integration degree.

Based on this, the embodiments of the present application provide a packaging carrier board embedding a packaged chip connecting device inside a glass carrier board so as to package multiple chips on the glass carrier board. This can solve the problem of arranging a TSV interposer between the packaging carrier board and the chip to a certain extent.

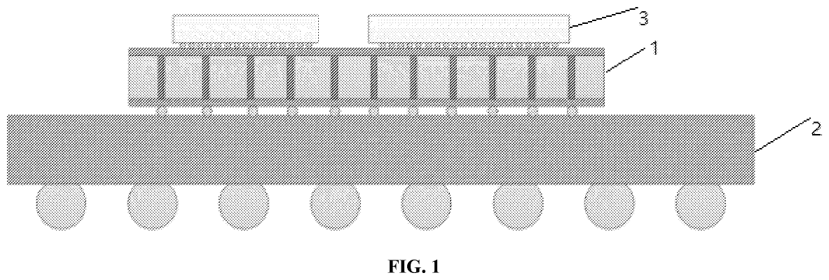

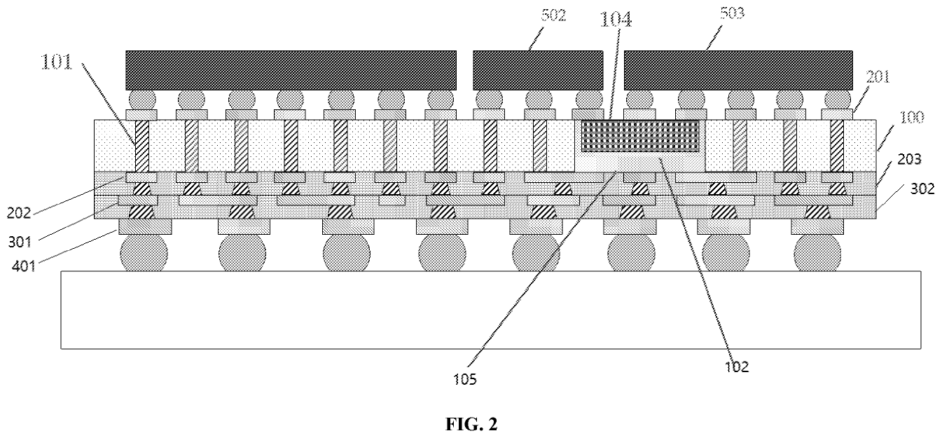

FIG. 2 shows a schematic diagram of a multichip interconnecting packaging structure provided in an embodiment of the present application.

As shown in FIG. 2, the multichip interconnecting packaging structure provided by an embodiment of the present application may include: a glass frame 100, a first line layer 201 and a second line layer 202 respectively arranged on the first surface and the second surface of the glass frame, a first via post 101 penetrating through the glass frame 100, a cavity 102 penetrating through the glass frame 100, a chip connecting device 104 embedded in the cavity 102, a first insulating layer 105 filling the cavity 102, and a first chip 502 and a second chip 503 arranged on the first line layer 201.

A terminal of the chip connecting device 104 is electrically connected to the first line layer 201; the first line layer 201 and the second line layer 202 are in conductive communication via the first via post 101; the first chip 502 and the second chip 503 are electrically connected to the chip connecting device 104 through the first line layer 201, respectively, so that the first chip 502 and the second chip 503 are interconnected with each other.

It should be understood that the first line layer 201 may include a pad connecting terminals of the chip connecting device 104. The first chip 502 and the second chip 503 can be electrically connected to the chip connecting device 104 through the pad.

An embodiment of the present application provides a multichip interconnecting packaging structure. A glass frame having a first via post 101 is used as an embedded packaging frame, the chip connecting device 104 is embedded and packaged inside the glass frame to form a packaging carrier board embedded with the chip connecting device 104, and a terminal of the chip connecting device 104 is connected to the first line layer 201. Multiple chips, such as a first chip 502 and a second chip 503, packaged on a glass carrier board can be electrically connected to the first line layer 201 connecting to the chip connecting device 104, thereby achieving the interconnection between multiple chips packaged on the packaging carrier board and the interconnection between the packaging carrier board and the chip so as to achieve the high-density integration of a packaging module.

In general, the first chip 502 and the second chip 503 may be a driver chip of an integrated circuit (an IC driver), or a field-effect tube (FET), etc. Multiple first chips 502 and second chips 503 may be provided, respectively. Multiple first via posts 101 may be provided, and the sizes of the multiple first via posts 101 may be the same or different. Multiple chip connecting devices 104 may also be provided as required.

In some embodiments, the chip connecting device 104 may be a thin film line layer, a silicon interposer, a glass interposer, or a chip, etc. to achieve high-precision interconnection between the first chip 502 and the second chip 503.

In some embodiments, the height of the chip connecting device 104 is less than the height of cavity 102. The first insulating layer 105 completely fills the cavity 102 so that the chip connecting device 10 is embedded in the first insulating layer 105 to achieve packaging.

In some embodiments, the first insulating layer 105 is coplanar with the second surface of the glass frame 100. In this manner, the second surface of the glass frame may have flatness, facilitating the manufacturing of the second line layer 202, and improving the yield of the multichip interconnecting packaging structure.

In some embodiments, the first line layer 201 may include a first pad connected to an end face of the first via post 101 and a second pad connected to a terminal of the chip connecting device 104; the first pad and the second pad may be electrically connected to the first chip 502 and/or the second chip 503, respectively. In this way, the interconnection of the first chip 502 and/or the second chip 503 with the chip connecting device 104 and the external substrate, respectively, can be achieved.

In some embodiments, a second insulating layer 203 and a third line layer 301 provided on the second line layer 202 are further included; the third line layer 301 and the second line layer 202 are in conductive communication through a second via post that penetrates through the second insulating layer 203. The thicknesses of the second insulating layer 203 and the third line layer 301 may be determined according to actual requirements.

In some embodiments, a third insulating layer 302 and a fourth line layer 401 provided on the third line layer 301 are further included; the fourth line layer 401 and the third line layer 301 are in conductive communication through a third via post that penetrates through the third insulating layer 302. The thicknesses of the third insulating layer 302 and the fourth line layer 401 may be determined according to actual requirements.

Based on the same inventive concept and corresponding to a multichip interconnecting packaging structure in any of the aforementioned embodiments, an embodiment of the present application further provides a manufacturing method for a multichip interconnecting packaging structure.

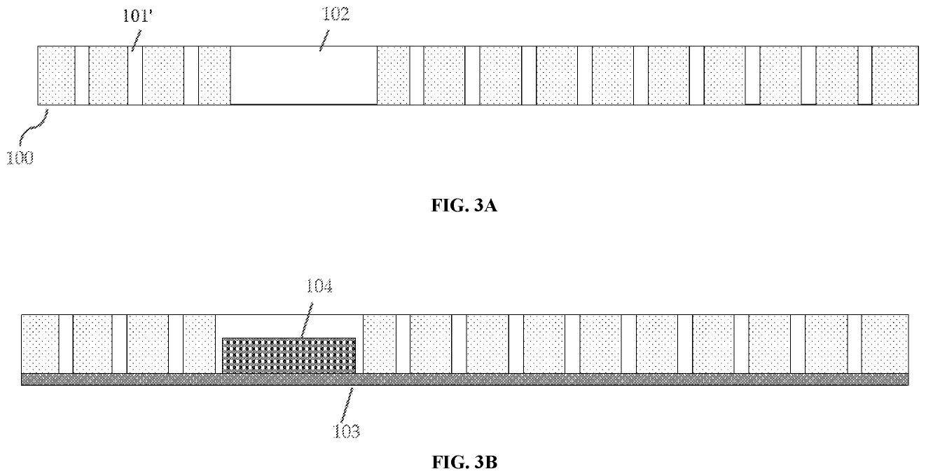

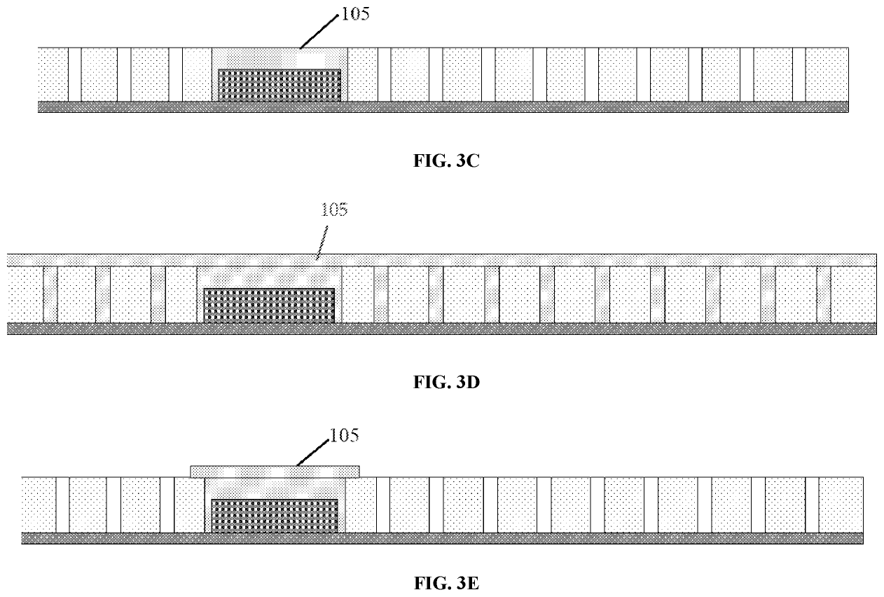

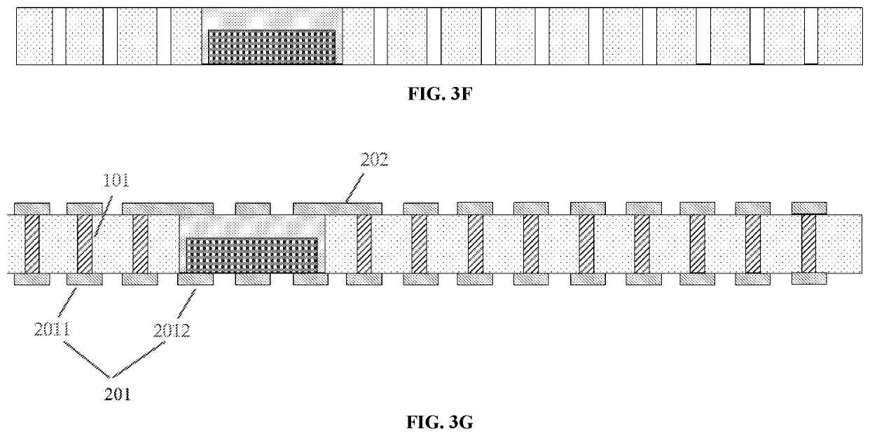

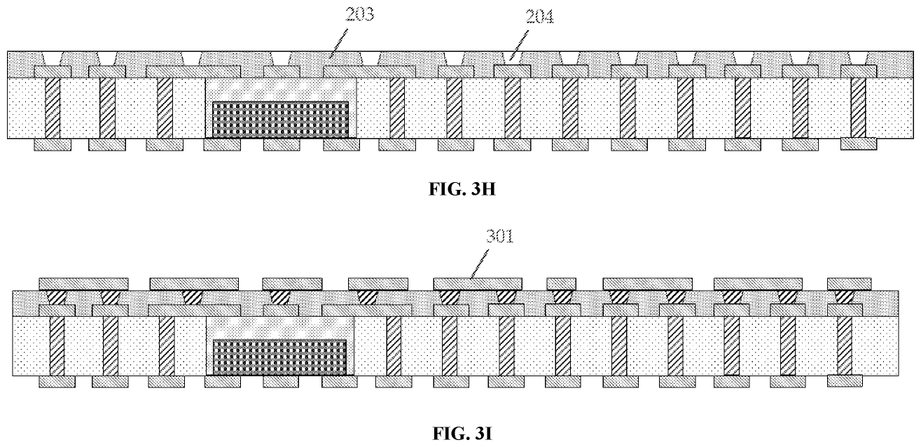

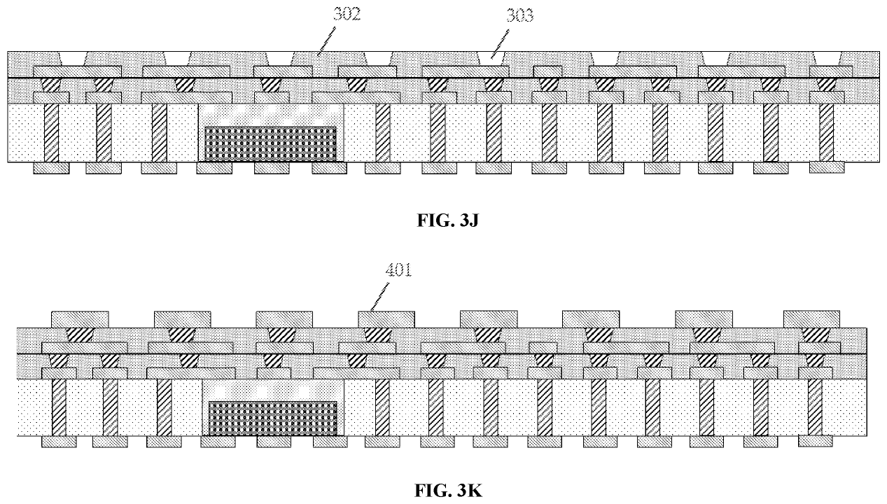

FIGS. 3A to 3K show schematic cross-sectional diagrams of intermediate structures in each step of a manufacturing method for the multichip interconnecting packaging structure in FIG. 2.

A manufacturing method for a multichip interconnecting packaging structure includes the following steps: preparing a glass frame 100, and forming a first via (Through G Via, TGV) 101′ penetrating through the glass frame 100 and a cavity 102 (Cavity) penetrating through the glass frame 100 on the glass frame 100-step (a), as shown in FIG. 3A. Typically, the glass frame 100 is clear glass, and the thickness of the glass frame 100 can be determined according to the requirements of the embedded chip connecting device 104. Generally, multiple first vias may be provided, and the size of multiple first vias may be the same or different. The size of the cavity 102 should be larger than the size of the chip connecting device to be packaged. Multiple through-cavities 102 may be provided. Specifically, the first via and the cavity 102 can be formed by means of laser post-etching. The concentration of the etchant may be adjusted according to the requirements of the etch rate and the etch depth. Preferably, the etchant is a hydrofluoric acid solution.

With the glass frame 100, the packaging carrier board can have a coefficient of thermal expansion close to that of the wafer substrate so that the multichip interconnecting packaging structure can have better reliability after subsequent chip packaging. In addition, compared with organic materials, it has better flatness, smoothness, and like performances, which is beneficial to the subsequent fabrication of a finer line.

Next, the chip connecting device 104 is mounted in the cavity 102 of the glass frame 100-step (b), as shown in FIG. 3B. Generally, the step includes the following sub-steps:
applying an adhesive layer 103 to the first surface of the glass frame 100; and
attaching the chip connecting device 104 to the adhesive layer 103 within the cavity 102.

The chip connecting device 104 is typically mounted to the bottom of the cavity 102 to facilitate the subsequent formation of a first line layer on the chip connecting device 104. By applying an adhesive layer, the pre-fixation of the chip connecting device 104 can be achieved, increasing the fixation strength of the chip connecting device 104 within the cavity 102. Preferably, the chip connecting device 104 may also be mounted in the middle of the cavity 102. In this way, the stability of the chip connecting device 104 can be improved.

A first insulating layer 105 is then formed within the cavity 102 to package the chip connecting device 104, as shown in FIG. 3C. Generally, the step includes the following sub-steps:
laminating a first insulating layer 105 on the second surface of the glass frame 100, and forming the first insulating layer 105 on the second surface of the glass frame 100, in the first via, and in the cavity 102, as shown in FIG. 3D. Generally, the first insulating layer 105 can be a photosensitive insulating material, and can be formed by being pressed fit on the second surface of the glass frame 100, in the first via, and in the cavity 102, so as to facilitate subsequent processes such as exposure and development.

The first insulating layer 105 is exposed and developed to leave only the first insulating layer 105 in the cavity 102 and on the surface of the glass frame 100 corresponding to the cavity 102, as shown in FIG. 3E. In general, the first insulating layer 105 except for that in the cavity region can be removed by exposure and development, so that only the first insulating layer 105 in the cavity region can remain, and the photosensitive medium on the second surface at the remaining positions and in the TGV hole can be removed.

The first insulating layer 105 other than that in the region of the cavity 102 is removed, resulting in the structure shown in FIG. 3C. In general, the first insulating layer 105 remaining on the second surface of the glass frame 100 can be removed by plasma etching or chemical polishing, etc. so that the first insulating layer 105 is coplanar with the second surface of the glass frame 100, so as to ensure the flatness of the glass frame 100, facilitate the subsequent structure manufacturing, etc.

Next, the adhesive layer 103, such as a tape, is removed, resulting in the structure shown in FIG. 3F. The adhesive layer can generally be removed by tearing or the like.

Then, a first line layer 201 and a second line layer 202 are formed on the first surface and the second surface of the glass frame 100, respectively, while a first via post 101 is formed in the first via, so that the first line layer 201 and the second line layer 202 are conductively communicated through the first via post 101-step (d), as shown in FIG. 3G. Generally, this step can include the following sub-steps:
forming a metal seed layer on the first surface and the second surface of the glass frame 100 respectively so as to cover the inner surface of the first via and the surface of the first insulating layer 105; respectively applying a photoresist layer on the first surface and the second
surface of the glass frame 100 and performing patterning to expose the metal seed layer;

electroplating copper on the exposed metal seed layer to form a first via post 101 in the first via and form a first line layer 201 and a second line layer 202 on the first surface and the second surface of the glass frame 100; and
removing the photoresist layer and etching the exposed metal seed layer.

Generally, forming the first line layer 201 may include: forming a first line layer 201 including a first pad 2011 connected to an end face of the first via post 101 and a second pad 2012 connected to a terminal of the chip connecting device 104.

Next, a second insulating layer 203 is formed on the second line layer 202, as shown in FIG. 3H. Typically, this step can include the following sub-steps:
laminating a second insulating layer 203 on the surface of the second line layer 202. The second insulating layer 203 may be a photosensitive insulating material or a thermosetting insulating material.

A second via 204 running through the second insulating layer 203 is formed at a position on the second insulating layer 203 corresponding to the first line layer 201.

Generally, when the second insulating layer 203 is a photosensitive insulating material, the second via 204 may be formed by a process such as exposure and development. When the second insulating layer 203 is a thermosetting insulating material, the second via 204 may be formed by laser drilling.

Then, a metal layer is manufactured on the surface of the second insulating layer 203 and within the second via 204 to form the second via post 204 and the third line layer 301, and the third line layer 301 is electrically connected to the second line layer 202 through the second via post 204, as shown in FIG. 3I. Generally, the manufacturing method for the third line layer 301 may include sub-steps of metal seed layer manufacturing, third line pattern manufacturing, third line layer 301 electroplating, film-stripping, metal seed layer etching, etc. Or it may include sub-steps such as metal seed layer manufacturing, whole surface porefilling electroplating, third line pattern manufacturing, etching and film-stripping of the third line layer 301, and the specific implementation of each sub-step may be the same as the manufacturing method for the first line layer 201 and the second line layer 202 as previously described, which will not be described in detail herein.

Next, a third insulating layer 302 is formed on the third line layer 301, as shown in FIG. 3J. Typically, this step can include the following sub-steps:
laminating a third insulating layer 302 on the surface of the third line layer 301. The third insulating layer 302 may be a photosensitive insulating material or a thermosetting insulating material. The materials of the third insulating layer 302 and the second insulating layer 203 may be the same or different, depending on specific requirements.

A third via 303 is formed at a position of the third insulating layer 302 corresponding to the second line layer 202. Generally, when the third insulating layer 302 is a photosensitive insulating material, the third via 303 may be formed by a process such as exposure and development. When the third insulating layer 302 is a thermosetting insulating material, a third via 303 may be formed by laser drilling.

Then, a metal layer is formed on the surface of the third insulating layer 302 and within the third via 303 to form the third via post 303 and the fourth line layer 401, and the fourth line layer 401 is connected to the third line layer 301 through the third via post 303, as shown in FIG. 3K. In this way, the electrical connection between the third line layer 301 and the fourth line layer 401 may be achieved through the third via post 303. Generally, the manufacturing method for the fourth line layer 401 may include sub-steps such as metal seed layer manufacturing, the fourth line pattern manufacturing, the fourth line layer 401 electroplating, film-stripping, and metal seed layer etching. Or it may include sub-steps such as metal seed layer manufacturing, whole surface porefilling electroplating, the fourth line pattern manufacturing, etching and film-stripping of the fourth line layer 401, and the specific implementation of each sub-step may be the same as the manufacturing method for the first line layer 201 and the second line layer 202 as previously described, which will not be described in detail herein.

Next, the first chip 502 and the second chip 503 are mounted (may be a flip chip) to the first line layer 201; the first chip 502 and the second chip 503 are respectively connected to the chip connecting device 104 via the first line layer 201 to interconnect the first chip 502 with the second chip 503-step (e), thus obtaining the multichip interconnecting packaging structure as shown in FIG. 2. In general, the first chip 502 and the second chip 503 are flip-chipped on the second pad extending from the chip connecting device 104, respectively, to be electrically connected to the chip connecting device 104, so that the interconnection of the first chip 502 and the second chip 503 is achieved through the connection to the chip connecting device 104.

In the present application, a multichip interconnecting packaging carrier board is obtained by embedding and packaging a chip connecting device 104 inside a glass carrier board. With the glass frame 100 having the TGV as the embedded packaging frame, the chip connecting device 104 is embedded and packaged inside the packaging carrier board, and the terminal pins of the chip connecting device 104 are led out to form a pad. In this way, the multiple chips packaged on the packaging carrier board can be soldered with the pad led out from the chip connecting device 104, so as to realize the interconnection of multiple chips packaged on the carrier board with each other, the interconnection between the packaging carrier board and the chip, and the interconnection between the packaging carrier board itself and the substrate, thereby realizing the high-density integration of the packaging module.

The present application does not require a TSV interposer which reduces the production costs; according to the present application, the chip connecting device 104 for achieving multichip interconnection is embedded and packaged inside the glass frame 100, effectively reducing the volume of the packaging module; the embedded and packaging position of chip connecting device 104 can be adjusted according to the interconnection position of multiple chips, providing high design freedom; the chip connecting device 104 is embedded and packaged inside the glass frame 100, which can achieve higher density integrated packaging while improving the reliability and stability of the packaging module; the thermal expansion coefficient of a glass material is close to that of a wafer substrate such that after chip packaging, the reliability is better; compared to organic substrate materials, glass materials are flatter and more smooth, enabling the manufacturing of a finer line and other advantages.

Those of ordinary skill in the art should understand that the discussion of any embodiment above is merely exemplary and is not intended to imply that the scope of the application (including the claims) is limited to these examples; combinations of technical features in the above embodiments, or between different embodiments, may also be made under the concept of the present application; the steps may be implemented in any order, and there may be many other variations of the different aspects of the embodiments of the present application as described above, which are not provided in detail for concision.

In addition, to simplify the explanation and discussion, and to avoid making the embodiments of the present application difficult to understand, well-known power source/grounding connections with integrated circuit (IC) chips and other components may or may not be shown in the provided drawings. In addition, the device can be shown in the form of a block diagram to avoid making the embodiments of the present application difficult to understand, and this also takes into account the fact that the details of the implementation modes of these block diagram devices are highly dependent on the platform on which the embodiments of the present application are to be implemented (i.e., these details should be fully within the understanding range of those skilled in the art). In the case where specific details (such as circuits) are elaborated to describe exemplary embodiments of the present application, it is apparent to those skilled in the art that the embodiments of the present application can be implemented without these specific details or with changes in these specific details. Accordingly, the description is to be regarded as illustrative rather than restrictive.

Although the present application has been described in conjunction with specific embodiments thereof, based on the previous description, many substitutions, modifications, and variations of these embodiments will be apparent to ordinary technical personnel in the art. For example, other memory architectures (such as Dynamic RAM (DRAM)) can use the discussed embodiments.

The embodiments of the present application are intended to cover all such substitutions, modifications, and variations that fall within the broad scope of the appended claims. Therefore, any omission, modification, equivalent replacement, improvement, etc. made within the spirit and principles of the embodiments of the present application should be included in the scope of protection of the present application.

What is claimed is:

1. A multichip interconnecting packaging structure comprising:
a glass frame having a first surface and a second surface;
a first line layer and a second line layer respectively provided on the first surface and the second surface of the glass frame;
a first via post penetrating through the glass frame;
a cavity penetrating through the glass frame;
a chip connecting device embedded in the cavity;
a first insulating layer filling the cavity to cover the chip connecting device; and
a first chip and a second chip provided on a surface of the first line layer,
wherein a terminal of the chip connecting device is connected to the first line layer;
the first line layer and the second line layer are in conductive communication through the first via post; the first chip and the second chip are connected to the chip connecting device through the first line layer to interconnect the first chip with the second chip.

2. The multichip interconnecting packaging structure according to claim 1, wherein the multichip interconnecting packaging structure is electrically connected to a substrate through the second line layer.

3. The multichip interconnecting packaging structure according to claim 2, wherein a height of the chip connecting device is less than that of the cavity.

4. The multichip interconnecting packaging structure according to claim 1, wherein the first line layer comprises a first pad connected to the first via post and a second pad connected to a terminal of the chip connecting device; and
the chip connecting device is electrically connected to the first chip and the second chip through the second pad, respectively.

5. The multichip interconnecting packaging structure according to claim 1, further comprising:
a second insulating layer on the second line layer; and
a third line layer on the second insulating layer,
wherein the third line layer and the second line layer are in conductive communication through a second via post penetrating through the second insulating layer.

6. The multichip interconnecting packaging structure according to claim 5, further comprising:
a third insulating layer on the third line layer; and
a fourth line layer on the third insulating layer,
wherein the fourth line layer and the third line layer are in conductive communication through a third via post penetrating through the third insulating layer.

7. The multichip interconnecting packaging structure according to claim 1, wherein the chip connecting device is selected from a thin film line layer, a silicon interposer, a glass interposer, or a chip.

8. A manufacturing method for a multichip interconnecting packaging structure, the method comprising:
preparing a glass frame, and forming, on the glass frame, a first via penetrating through the glass frame and a cavity penetrating through the glass frame;
mounting a chip connecting device in a cavity of the glass frame;
forming a first insulating layer in the cavity so as to package the chip connecting device;
forming a first line layer and a second line layer respectively on a first surface and a second surface of the glass frame, and forming a first via post in the first via so that the first line layer and the second line layer are in conductive communication with each other through the first via post; and
mounting a first chip and a second chip to the first line layer, wherein the first chip and the second chip are respectively connected to the chip connecting device through the first line layer to interconnect the first chip with the second chip.

9. The method according to claim 8, wherein the mounting comprises:
applying an adhesive layer on the first surface of the glass frame; and
attaching the chip connecting device to the adhesive layer in the cavity. The method according to claim 9, wherein the forming of the first insulating layer comprises:
laminating a first insulating layer on the second surface of the glass frame so that the first insulating layer fills the cavity and covers the chip connecting device; and
exposing and developing the first insulating layer to leave only the first insulating layer in the cavity so that the first insulating layer is coplanar with the second surface.

11. The method according to claim 9, further comprising:
removing the adhesive layer after the forming of the first insulating layer and before the forming of the first line layer and the second line layer.

12. The method according to claim 8, wherein the forming of the first line layer comprises:
forming a first pad connected to the first via post and a second pad connected to the chip connecting device.

13. The method according to claim 8, further comprising:
laminating a second insulating layer on a surface of the second line layer;
forming a second via post running through the second insulating layer on the second insulating layer; and
forming a third line layer on the second insulating layer, so that the third line layer is electrically connected to the second line layer through the second via post.

14. The method according to claim 13, further comprising:
laminating a third insulating layer on the surface of the third line layer;
forming a third via post running through the third insulating layer on the third insulating layer; and
forming a fourth line layer on the third insulating layer, so that the fourth line layer is electrically connected to the third line layer through the third via post.

15. The method according to claim 14, further comprising:
electrically connecting the fourth line layer to a substrate such that the multichip interconnecting packaging structure is interconnected with the substrate.
